(19) United States
(12) Patent Application Publication
(10) Pub. No.: US 2011/0001036 A1
(43) Pub. Date: Jan. 6, 2011

(54) SYSTEM FOR IMAGING AN OBJECT

(75) Inventors: Sjoerd Stallinga, Eindhoven (NL); Dirk Leo Joep Vossen, Eindhoven (NL); Augustinus Braun, Heeze (NL); Bernardus Hendrikus Wilhelmus Hendriks, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 12/446,462

(22) PCT Filed: Oct. 15, 2007
(86) PCT No.: PCT/IB2007/054181

§ 371 Date: Apr. 21, 2009

(30) Foreign Application Priority Data
Oct. 24, 2006 (EP) 06122861.5

(51) Int. Cl. H01L 27/00; G02B 7/02; G02B 27/30; G02B 27/12; G21K 1/02

(52) U.S. Cl. 250/208.1; 359/813; 359/641; 359/622; 359/355; 359/356; 378/147

(57) ABSTRACT

A device (100) for imaging an object (101), wherein the device (100) comprises an objective lens (102) adapted to manipulate a beam of electromagnetic radiation (103) transmitted through the object (101), a collimator lens (104) adapted to manipulate the beam of electromagnetic radiation (103) transmitted through the objective lens (102), and an actuator (105) adapted for displacing the objective lens (102) in a direction essentially parallel and in a direction essentially perpendicular to a propagation direction of the beam of electromagnetic radiation (103) between the objective lens (102) and the collimator lens (104), wherein the objective lens (102) and the collimator lens (104) are arranged so that the beam of electromagnetic radiation (103) between the objective lens (102) and the collimator lens (104) is essentially parallel.

The invention relates to a device for imaging an object.

The invention further relates to an apparatus for imaging an object.

Beyond this, the invention relates to a method of imaging an object.

Optical imaging systems may be used in many different technical fields, for instance in the field of medical devices.

US 2004/0223226 discloses a multiple-axis imaging system having individually-adjustable optical elements. The system comprises a plurality of optical elements having respective optical axes and being individually disposed with respect to one another to image respective sections of an object, and a plurality of individually-operable positioning devices corresponding to respective optical elements for positioning the optical elements with respect to their respective optical axes. The positioning devices are specifically adapted to adjust the axial position, lateral position and angular orientation of the optical elements with respect to their respective optical axes. The system is particularly adapted for use as a microscope array, and the positioning devices may be micro-actuators.

It may happen with these conventional imaging systems that the operation is too complicated, since the involved motion mechanism is complex.

It is an object of the invention to provide an imaging system allowing a simple operation.

In order to achieve the object defined above, a device for imaging an object, an apparatus for imaging an object, and a method of imaging an object according to the independent claims are provided.

According to an exemplary embodiment of the invention, a device for imaging an object is provided, wherein the device comprises an objective lens adapted to manipulate a beam of electromagnetic radiation after interaction with, particularly transmitted through (alternatively reflected at), the object, a collimator lens adapted to manipulate the beam of electromagnetic radiation transmitted through the objective lens, and an actuator adapted for displacing the objective lens in a direction essentially parallel and in at least one direction (that is to say in one direction or in two directions which may be perpendicular to one another) essentially perpendicular to a propagation direction of the beam of electromagnetic radiation between the objective lens and the collimator lens, wherein the objective lens and the collimator lens are arranged so that the beam of electromagnetic radiation between the objective lens and the collimator lens is essentially parallel.

According to another exemplary embodiment of the invention, an apparatus for imaging an object is provided, wherein the apparatus comprises an array formed by a plurality of devices having the above mentioned features.

According to still another exemplary embodiment of the invention, a method of imaging an object is provided, wherein the method comprises manipulating, by an objective lens, a beam of electromagnetic radiation after interaction with, particularly transmitted through (alternatively reflected at), the object, manipulating, by a collimator lens, the beam of electromagnetic radiation transmitted through the objective lens, displacing the objective lens in a direction essentially parallel to a propagation direction of the beam of electromagnetic radiation between the objective lens and the collimator lens thereby adjusting a focus setting, acquiring an image, subsequently displacing the objective lens in a direction essentially perpendicular to a propagation direction of the beam of electromagnetic radiation between the objective lens and the collimator lens, maintaining or re-adjusting the focus setting, acquiring another image, repeating these steps so as to collect a multiplicity of images, processing the collection of images to form an overall image, and arranging the objective lens and the collimator lens so that the beam of electromagnetic radiation between the objective lens and the collimator lens is essentially parallel.

According to yet another exemplary embodiment of the invention, a computer-readable medium is provided, in which a computer program of imaging an object is stored which, when being executed by a processor, is adapted to control or carry out a method having the above mentioned features.

According to still another exemplary embodiment of the invention, a program element of imaging an object is provided, which program element, when being executed by a processor, is adapted to control or carry out a method having the above mentioned features. The term “program element” may particularly denote any software component which is capable of controlling the scanning, signal detection and/or signal processing scheme for imaging an object under investigation.

Signal processing and component control for improving image quality and/or operation speed which may be performed according to embodiments of the invention can be realized by a computer program, that is by software, or by using one or more special electronic optimization circuits, that is in hardware, or in hybrid form, that is by means of software components and hardware components.

According to an exemplary embodiment of the invention, a microscope is provided having an objective lens and a collimator lens, the objective lens being actuable in a direction parallel to a beam path and in one or both directions perpendicular thereto, so that an object to be imaged (for instance a tissue sample) may be scanned even with a single objective lens and a single actuator. By designing the optical system in a manner that the beam of electromagnetic radiation between the objective lens and the collimator lens is essentially parallel, a detector and also the collimator lens do not have to be moved, so that only few elements and consequently only a low weight have has to be moved, allowing a faster, simpler and more accurate motion. More precisely, the objective lens and the collimator lens may be arranged so that sub-beams of the beam of electromagnetic radiation originating from the same portion of the object and being directed towards the same portion of a detector are essentially parallel at least between the objective lens and the collimator lens. Thus, the design of the optical arrangement may be such that all beams related to one object point and focused to one image point on the detector are parallel between the objective lens and the collimator lens.

According to an exemplary embodiment of the invention, it may be made possible to enlarge the field of an imaging system, in particular a microscope, by acquiring a multiplicity of images and stitching these images together to form a single overall image of a field larger than the field of the imaging system. Acquiring the multiplicity of images can be done by placing the object or the entire imaging system on a translation table, so that the object and imaging system can be displaced with respect to each other in the two directions perpendicular to the optical axis. An issue with such a method is that the movables parts are bulky, and according to an exemplary embodiment of the invention only a part of the imaging system is displaced, namely the objective lens. This allows greater speed of displacement. A technical measure which allows such a system to work is that the beam directly downstream of the objective lens is essentially parallel.

The actuator for displacing the objective lens in the direction perpendicular to the propagation direction of the beam may be adapted for displacing the objective lens for scanning and imaging a corresponding portion of the object. Thus, in each spatial position of the objective lens, a part of the image is imaged, and the image parts may then be put together for forming an entire image.

According to another exemplary embodiment, a microscope array formed by a plurality of such microscopes may be provided. Then, each of the microscopes can scan an assigned portion of an object. It is also possible that a plurality of objects are scanned simultaneously.

According to an exemplary embodiment, an object imaging device, particularly a microscope, can be equipped with a scanning system which is similar to optical storage (e.g. DVD) readout systems (see for instance J. Schleipen, B. H. W. Hendriks, S. Stalling a, “Optical Heads”, Chapter “Encyclopedia of Optical Engineering”, pp. 1667 to 1693, Marcel Dekker, New York, 2003).

An exemplary field of application of exemplary embodiments of the invention is DNA cytometry. By using a microscope or a microscope array according to embodiments of the invention in DNA cytometry, it is possible to acquire an image in a fast manner, and with a high throughput (that is to say with a high value of scanned area per time unit). Further, the mass to be moved by a motion mechanism for scanning an object may be kept small, since the parallel beam paths between objective lens and the collimator lens makes it possible to move only a small portion of the device, whereas the main mass may be kept fixed. Moreover, since the largest part of the optical imaging system may be kept spatially fixed, distortions along the optical path may be prevented.

According to an exemplary embodiment, an array of microscopes is provided (for instance an array of 10×10=100 small microscopes which may be arranged in a matrix-like manner, for instance). Actuators may move objective lenses of each of the microscopes in order to scan a corresponding portion of an object. The used actuators may be magnet coil systems. Activating the coil by a current or voltage signal may generate an electromagnetic force between the magnet and the coil which may, by force transmission (for instance using tiny wires), move the objective lenses as well. However, piezoelectric actuators or other kinds of actuators are possible as well.

It may be advantageous to group lenses to form groups, like pairs, arrangements of three lenses, arrangements of four lenses, etc. Such a grouping may further improve the efficiency of the scanning procedure. However, it is also possible to have individual objective lenses, that is exactly one objective lens per microscope.

According to an exemplary embodiment, an array microscope for DNA cytometry is provided, for visualization of DNA in the (cell) nuclei for detection of cancer or other diseases.

Particularly, an array microscope may be provided in which each microscope comprises at least two lens elements (namely an objective lens and a collimator lens). Systems for displacing the at least one objective lens along the focus direction (that is to say along a propagation direction of the electromagnetic beam) and along at least one of the remaining directions orthogonal to the focus direction may be provided. Particularly, such an array microscope may be used in DNA cytometry.

More particularly a telescope-like optical configuration may be provided in which the beam between the objective lens and the collimator lens in front of a detector (for instance a CCD, charge coupled device) is substantially parallel. This may allow for an image acquisition mode in which the objective lens is displaced in the direction orthogonal to the optical axis. If the intermediate beam is not substantially parallel, the image might shift over the detector. Thus, this principle may be applied to an array microscope (comprising a plurality of microscopes) but also to a single microscope in which the lateral displacement of the objective lens may be used to broaden the field by taking multiple images and stitching them together.

In other words, a microscope may be provided comprising at least two lens elements (namely an objective lens and a collimator lens), containing means for displacing at least the objective lens in the focus direction and in at least one of the two directions orthogonal to the focus direction, wherein the beam in between the at least two lens elements may be substantially parallel. Particularly, an array of microscopes may be provided wherein each microscope is designed in such a manner.

Furthermore, a method of acquiring an image of a field larger than the field of the microscope may be provided by taking multiple images, each image being laterally displaced with respect to the others by displacing the displaceable lens element according to the above-described microscope (array) in the lateral direction, and subsequently stitching the multiple images together to form an overall image. This method can be applied particularly advantageously in DNA cytometry.

Next, some aspects regarding systems for DNA cytometry will be explained. Based on these considerations and recognitions, exemplary embodiments of the invention have been developed.

Conventionally, cancer may be diagnosed histologically on tissue sections from biopsies obtained from macroscopically suspicious surfaces. The technique of DNA-cytometry is based on the presence of numerical and/or structural aberrations in the chromosomes in the nucleus of the cell (aneuploidy). These aberrations are only found in tumor tissue. Detection of DNA-aneuploidy allows for very early diagnosis of cancer, often years ahead of the histological diagnoses on biopsies. The stage of aneuploidy (or the amount of “excess” DNA material) is a measure for how far the cancer has developed. For the method of DNA-cytometry, clinical (lab) data is available for cancers of oral cavity, lungs, larynx, thyroid and uterine cervix.

G. Haroske, F. Giroud, A. Reith and A. Bocking, “1997 ESACP consensus report on diagnostic DNA image cytometry”, Analytical Cellular Pathology 17 (1998) 189-200 give an overview over conventional DNA cytometry methods.

In DNA-cytometry, a brush or a fine needle biopsy may be taken and subsequently colored with Fuelgen-staining. This staining binds to the DNA of cells and allows for the determination of the amount of DNA present in the cell nucleus. This may be done via a measurement of the integrated optical density (IOD). From a histogram of IODs of all cells in the sample, the (possible existing) cancerous cells can be determined. Either a pre-selection of suspicious cells are measured (so called first protocol) or, alternatively, all cells in the sample are measured (so called second protocol).

The first protocol needs a trained pathologist to do the pre-selection (labor-intensive) and is therefore expensive. In the second protocol, all cells are measured and only the most suspicious cells are viewed by a pathologist. Hence for each cell the IOD and an image of the cell is measured and stored. This makes the method much less labor intensive but as all cells have to be measured at several heights in the sample in order to obtain the right focused imaged of the cell, the technique is rather time consuming. Since for each slide the full microscope system and software is needed, this low throughput of slides makes the measurement expensive again.

Based on upon the above considerations, exemplary embodiments of the invention provide a system capable to measure the IOD of the nuclei of all cells in the sample at a high speed and image the cells and their nuclei at the same time in order to allow final visual inspection of the suspicious cells for control. More particularly, the sample may be imaged with an array of compact, cheap and simple microscopes.

Exemplary fields of application of embodiments of the invention are cancer screening and early cancer detection based on fast in vitro DNA cytometry.

Next, further exemplary embodiments of the device will be explained. However, these embodiments also apply to the apparatus and to the method.

The device may comprise one or more further objective lenses, wherein the objective lens and the further objective lens(es) may be grouped to form a pair/group of objective lenses. Such grouped objective lenses (it is also possible to group three or more objective lenses) may be moved cooperatively so as to increase the efficiency of the system, and keep the effort for the moving mechanism as small as possible. Furthermore, by grouping such lenses, a plurality of lenses may be used simultaneously for transmitting electromagnetic radiation. This keeps measurement times short.

The pair of objective lenses may be arranged to be displaceable in common by the respective actuators. In other words, only a single motion mechanism and a simple motion control may be sufficient, thereby reducing the efforts and size when designing the device.

The device may comprise a phase plate arranged, in an electromagnetic radiation propagation direction, downstream of the objective lens. For instance, such a phase plate may be arranged between the objective lens and the collimator lens. Such a phase plate may be placed in the back focal plane of the objective lens when the microscope is used for phase contrast applications.

Additionally or alternatively, a wavelength filter, particularly a high-pass wavelength filter, may be arranged in an electromagnetic radiation propagation direction, downstream of the objective lens. Such a wavelength filter may be arranged between the objective lens and the collimator lens. Such a (high-pass) wavelength filter may be implemented when the microscope is used for fluorescence contrast applications.

The device may be adapted as a microscope. A microscope may be denoted as an imaging device which generates a magnified image of an object.

In the following, further exemplary embodiments of the apparatus will be explained. However, these embodiments also apply to the device and to the method.

The objective lenses of the devices may be staggered with respect to one another. More particularly, the pairs of objective lenses of the devices may be staggered with respect to one another. In other words, adjacent objective lens pairs (with individual lenses having a distance of 12 mm from one another) may be displaced by a specific distance, for instance by 1 mm. Therefore, it is possible to use the plurality of staggered objective lenses/lens pairs/lens groups to scan portions of the object, thereby making the analysis more efficiently and allowing for a high throughput analysis.

The pairs/groups of objective lenses of the devices may be staggered with respect to one another along the direction essentially perpendicular to the propagation direction of the beam of electromagnetic radiation along which direction the pairs of the objective lenses of the devices are displaceable by the actuators. Therefore, the staggering direction and the lateral motion direction of the collimator lenses may be identical. The staggering distance may then be selected so that lateral oscillation of adjacent staggered lenses (or groups of lenses) allow to scan the object without invisible portions. A slight overlap of the scanned portions is possible and may simplify stitching together the individual image portions.

The apparatus may comprise a motion mechanism adapted for displacing the objective lenses of the plurality of devices relative to the object in a direction essentially perpendicular to the direction essentially parallel and to the direction essentially perpendicular to the propagation direction of the beam of electromagnetic radiation. Such a motion mechanism, for instance a linear stepper motor, may move the object (which may be mounted on a sample holder) and may keep the objective lenses spatially fixed. This may be advantageous, since a motion of the relatively heavy objective lenses may be avoided and these optical elements can be kept fixed. However, alternatively it is possible that the objective lenses are moved and that the object (mounted on a sample holder) remains fixed. By moving objects or objective lenses perpendicular to the lateral displacement, a simultaneous scan of a plurality of objects is possible. Therefore, batches of objects may be investigated.

The apparatus may comprise a sample holder adapted for holding one or a plurality of objects to be imaged. This may allow to perform a high throughput analysis.

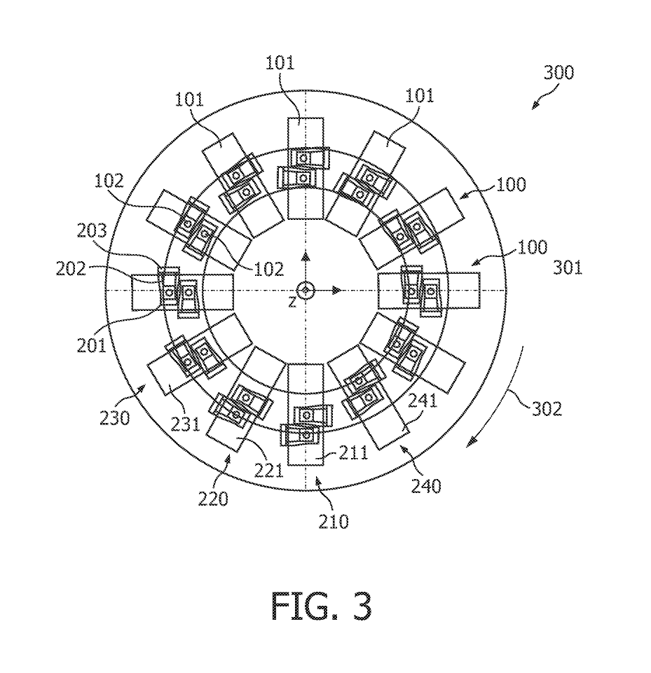

Particularly, the motion mechanism may be adapted for displacing the sample holder to image the plurality of objects using the plurality of devices. For this purpose, the motion mechanism may displace the objective lenses of the plurality of devices relative to the object using a linear displacement or a relative rotation. A relative rotation (see FIG. 3) may be preferred since this may allow to avoid or reduce dead time. According to one embodiment, the various samples may be mounted on a rotatable wheel, and the lenses may be spatially fixed. According to another embodiment, the samples or objects may be spatially fixed, and the objective lenses may be mounted on a rotatable wheel.

The apparatus may comprise an electromagnetic radiation source adapted to generate the beam of electromagnetic radiation to be directed to the object. Such an electromagnetic radiation source may be any kind of lamp, or a laser, etc.

The electromagnetic radiation source may particularly be adapted to generate an essentially monochromatic beam of electromagnetic radiation. The term “essentially monochromatic” may denote that Δλ<<λ, wherein λ is the (average) wavelength of the electromagnetic radiation source and Δλ is the spectral bandwidth of the electromagnetic radiation source. By an essentially monochromatic illumination, the accuracy of the imaging procedure may be improved.

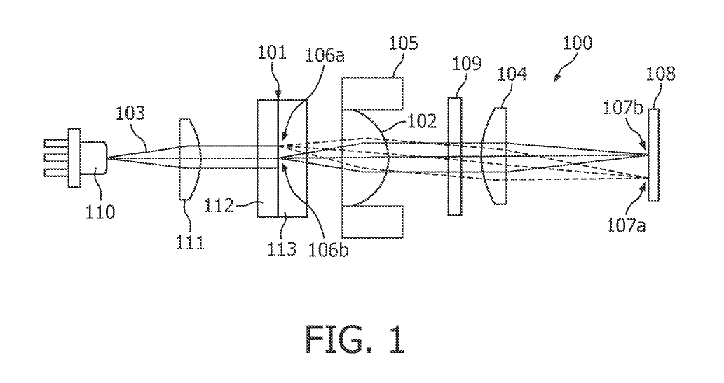

The electromagnetic radiation source may be adapted to generate an essentially parallel beam of electromagnetic radiation. It may be not or not only the illumination optics being a key to having parallel beams between objective and collimator. In fact, an exactly parallel illumination beam may be obtained for an ideal point source (for example a laser). In practice, a spatially extended source such as a LED or several types of lamps, may be used. The illumination then comes from (an infinitely large) number of point sources, each point source giving a parallel illumination beam at the object, the parallel beam making an angle with the optical axis proportional to the distance between the point source and the optical axis. Adding all parallel beams it then follows that an entire field of object points is illuminated, each object point in the field being illuminated by a converging cone of light, the top angle of the cone being determined by the illumination optics and the lateral extension of the light source. This type of illumination may be called Köhler-illumination and one type of illumination in microscopes (see M. Born and E. Wolf, “Principles of Optics”, 6th edition, p. 522-526, Cambridge University Press, 1980, ISBN 0521639212). Thus, in this regard, the light source in FIG. 1 is merely schematic.

The electromagnetic radiation source may be adapted to generate the beam of electromagnetic radiation of at least one of the group consisting of optical light, infrared radiation, ultraviolet radiation, and X-rays. The optical light domain may include the wavelength region between 400 nm and 800 nm. The infrared radiation may include the wavelength region with wavelengths higher than those of optical light, and ultraviolet radiation has wavelengths shorter than those of optical light. X-rays may have energies in the order of magnitude of kilo electron volts (keV). However, the use of optical light may be preferred for specific applications, like DNA cytometry.

The apparatus may comprise a detector unit comprising an array of detector elements arranged to detect the beam of electromagnetic radiation transmitted through the collimator lens. Examples for such a detector unit is a CCD (charge coupled device) or a CMOS sensor array.

The detector unit may be adapted to detect the image of the object and may be adapted to detect an integrated optical density (IOD). Particularly, the apparatus may be adapted to image the object for a plurality of focal positions. Taking this measure, for instance by allowing the object of lenses to be moved along the beam path, makes the apparatus appropriate for DNA cytometry applications.

The device may be adapted to image tissue of a physiological object. The term “physiological object” may denote a human being, an animal or a plant. Therefore, biological information may be derived with the device, for example with in vivo or in vitro investigations.

The device may be used in many different technical fields, for instance as a microscope, as a cytometry device (particularly as a DNA cytometry device), as a cancer detection device, as a cancer screening device, or as a high throughput screening device (for instance for biological, genetic or pharmaceutical applications). Other exemplary applications are a malaria screening device, a cell imaging device, array imaging, or a multi-well plate scanner.

In the following, further exemplary embodiments of the method will be explained. However, these embodiments also apply to the device and to the apparatus.

The method may further comprise adjusting a focus setting by displacing the objective lens in the direction essentially parallel to the propagation direction (between the objective lens and the collimator lens) of the beam of electromagnetic radiation, acquiring data related to an image of at least a portion of the object, subsequently displacing the objective lens in the direction essentially perpendicular to the propagation direction (between the objective lens and the collimator lens) of the beam of electromagnetic radiation, acquiring data related to another image of at least another portion of the object, and processing the data related to the image of the portion of the object and the data related to the other image of the other portion of the object to form an overall image of the object. In other words, multiple images of different portions of the object may be taken by moving the objective lens, and may then be stitched together to reconstruct a complete image of the object.

The method may further comprise re-adjusting the focus setting (for instance by displacing the objective lens in the direction essentially parallel to the propagation direction) before acquiring the data related to the other image of the other portion of the object. Alternatively, it is possible to maintain the focus setting.

The aspects defined above and further aspects of the invention are apparent from the examples of embodiment to be described hereinafter and are explained with reference to these examples of embodiment.

The invention will be described in more detail hereinafter with reference to examples of embodiment but to which the invention is not limited.

FIG. 1 illustrates a device for imaging an object according to an exemplary embodiment of the invention.

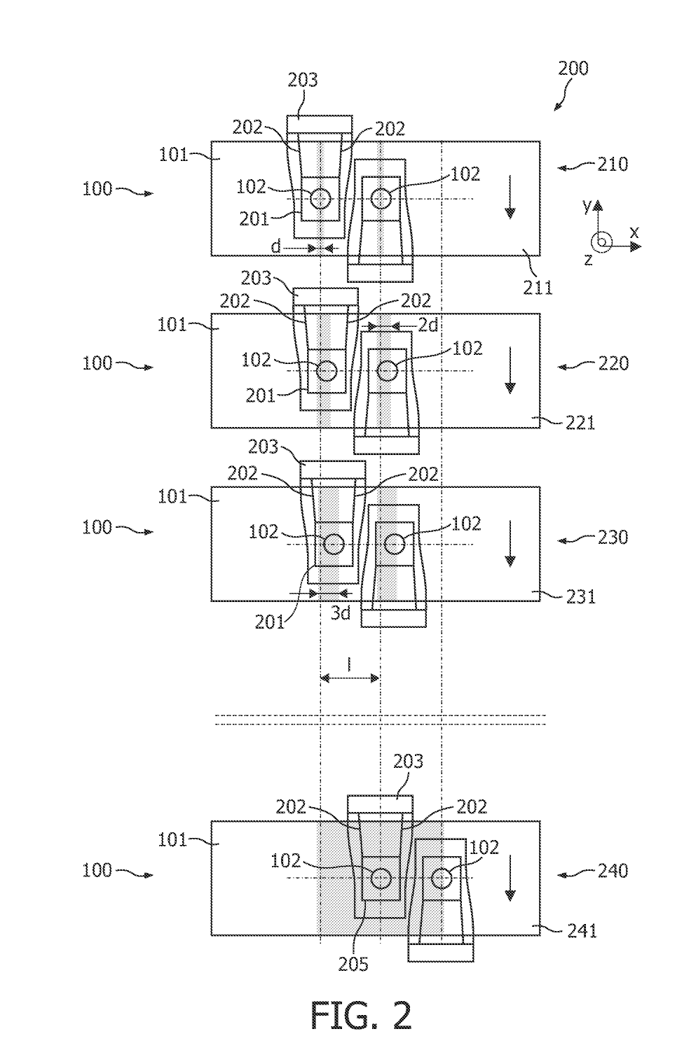

FIG. 2 illustrates an objective lens array of a device for imaging an object according to an exemplary embodiment of the invention.

FIG. 3 illustrates an objective lens array of a device for imaging an object according to an exemplary embodiment of the invention.

The illustration in the drawing is schematically. In different drawings, similar or identical elements are provided with the same reference signs.

In the following, referring to FIG. 1, a microscope 100 according to an exemplary embodiment of the invention will be explained.

The device 100 is adapted for imaging an object 101, namely a tissue sample. The device 100 comprises an objective lens 102 adapted to manipulate a beam of electromagnetic radiation 103 transmitted through the object 101. Further, a collimator lens 104 is provided to manipulate the beam of electromagnetic radiation 103 transmitted through the objective lens 102. An actuator 105 is provided for displacing the objective lens 102 in a direction essentially parallel and in at least one direction essentially perpendicular to a propagation direction of the beam of electromagnetic radiation 103 (according to FIG. 1, from left to the right) between the objective lens 102 and the collimator lens 104.

As can be taken from FIG. 1, the optical arrangement 100, and particularly the objective lens 102 and the collimator lens 104, are positioned and designed (regarding material, geometrical and optical properties) so that the beam of electromagnetic radiation 103 between the objective lens 102 and the collimator lens 104 is essentially parallel. More precisely, each object point 106a, 106b generates beam portions (see dotted lines and solid lines of the beam 103) which are manipulated by the optical elements 102, 104 in such a manner that corresponding image points 107a, 107b are focused on a detector 108. Particularly, the object point 106a is focused on the image point 107a. The object point 106b is focused on the image point 107b. In the path between the objective lens 102 and the collimator lens 104, the sub-beams 103 related to the object point 106a and to the image point 107a are essentially parallel to one another, and the sub-beams 103 related to the object point 106b and to the image point 107b are essentially parallel to one another.

A phase plate 109 may be optionally arranged, in the electromagnetic radiation propagation direction, downstream of the objective lens 102, particularly between the objective lens 102 and the collimator lens 104. Alternatively, the phase plate 109 may be substituted by a wavelength filter, particularly a high-pass wavelength filter, arranged, in an electromagnetic radiation propagation direction, downstream of the objective lens 102, particularly between the objective lens 102 and the collimator lens 104.

More particularly, FIG. 1 is a schematic view of an individual microscope element 100. Light is emitted by a light source 110. It is also possible that a plurality of light sources 110 are provided. The emitted beam of light 103 is made essentially parallel by a collimating lens 111, passes through a first substrate 112 of a sample holder and thereby illuminates the object layer 101. The light modified by the object layer 101 passes through a second substrate 113 of the sample holder, the objective lens 102 placed on the actuator 105, optionally the plate 109, the collimator lens 104, and is incident on the CCD detector 108, for instance a pixel detector such as a CCD. According to an exemplary embodiment, one or both of the substrates 112, 113 may be omitted. In such a scenario the sample 101 may be fixed at a single substrate or may be simply be placed in the beam path.

The object plane 106a, 106b and the image plane 107a, 107b are optically conjugate, meaning that light 103 emanating from object point 106a is collected at image point 107a, and light 103 emanating from object point 106b is collected at image point 107b. The actuator 105 can adjust the focal position on the object 101 with respect to the microscope 100 and can displace the lens 102 in one of the directions perpendicular to the focus direction (which focus direction is a direction from the left-hand side of FIG. 1 to the right-hand side of FIG. 1). The plate 109 may be omitted when the microscope 100 is used for standard absorption contrast. The plate 109 may be a phase plate placed in the back focal plane of the objective lens 102 when the microscope 100 is used for phase contrast. The plate 109 may be a wavelength filter (high-pass) when the microscope 100 is used for fluorescence contrast.

FIG. 1 shows the optical setup of an individual microscope element 100 including the objective lens 102 placed on the actuator 105 and the image sensor 108 (CCD or a CMOS sensor).

The objective lens 102 can be a cheap plastic objective lens (for instance having a value NA=0.65) for instance of a type which may conventionally be used for DVD readout. The actuator 105 (which can move the lens 102 along the focus direction and along one of the directions perpendicular to the focus direction, for example perpendicular to the paper plane of FIG. 1) can be an actuator as implemented in the field of optical data storage.

The image sensor 108 can have a relatively low resolution (for instance 0.25 Megapixel).

The sample 101 may be illuminated with a broad parallel monochromatic beam 103. The objective lens 102 may be used for red light (655 nm), but it can also function with sufficient quality at a difficult wavelength, like green light (about 500 to 600 nm). However, since the objective lens 102 cannot work simultaneously for these wavelengths with the highest accuracy, it may be advantageous that the illumination is essentially monochromatic.

A throughput of an array microscope 100 for instance the one shown in FIG. 2, can be estimated as follows:

The field of an objective lens may have a diameter (neglecting field curvature) of 50 μm, so each image may have an area (\sqrt{2}x50 μm)²)=0.005 mm², using N lenses in parallel the area is N×0.005 mm². With a 50 Hz frame rate of the camera 108, the throughput is 50 Hz×N×0.005 mm²=N×0.25 mm²/s. For example, taking N=24 gives that an area of 2 cm×2 cm for seven different focus heights is imaged in about 7×(20 mm)²/(24×0.25 mm²/s)=8 minutes. Consequently, the operation of the device may be significantly accelerated compared to conventional approaches.

FIG. 2 shows a plan view of a part of an apparatus 200 for imaging the object 101. The apparatus 200 comprises a plurality of devices 100 according to the above-described FIG. 1.

FIG. 2 shows a coordinate system with axes x, y and z, wherein x is a direction along which the collimator lenses 102 are displaceable. The y-direction indicates a direction along which, as will be described below in more detail, samples 105 may be shifted, for instance using a stepper motor. The direction z corresponds to the horizontal direction of FIG. 1, that is to say the general propagation direction of the beam 103. In other words, the beam 103 propagates out of the paper plane of FIG. 2. Above the paper plane of FIG. 2, the detector 108 is positioned.

More particularly, FIG. 2 shows a plurality of samples 101. All of these samples may be scanned in a common procedure.

The circle around reference numerals 102 denotes a lens, and the surrounding rectangle 201 denotes a lens mount. Springs (tiny wires) 202 connect the lenses 102 with actuator magnets 203. The magnets 203 cooperate with coils (not shown) to generate electromagnetic forces which may have an impact on the springs 202 to move the lens 102 in the x-direction and/or in the z-direction.

As can be taken from FIG. 2, for each of the microscope units 100, two collimator lenses 102 are grouped to form a group of a pair of objective lenses 102, 102. The respective groups of objective lenses 102, 102 are displaceable in common/in a correlated manner by the actuator 203.

Particularly, referring to the first microscope unit 210 shown on the top of FIG. 2, a first sample 211 passes a first pair of lenses 102, 102.

As can be shown in the second row microscope unit 220 in FIG. 2, a second sample 221 passes the second pair of lenses 102, 102. This pair 102, 102 is staggered by about d=1 mm with respect to the first pair 102, 102.

A third sample 231 passes a third microscope unit 230 comprising a third pair of lenses 102, 102. This pair 102, 102 is staggered by about 1 mm with respect to the second pair of lenses 102, 102, and so on.

Finally, a twelfth sample 241 passes a twelfth microscope unit 240 comprising a twelfth pair of lenses 102, 102 shown at a bottom part of FIG. 2. These lenses 102, 102 finalize the system, so that the whole area of the sample 101 has been imaged.

Therefore, FIG. 2 shows an example of an array microscope 200 using 24 actuators 203 and using 24 objective lenses 102. The objective lenses 102 are placed in twelve pairs. The lenses 102 in each pair are separated by about 1=12 mm. The actuator 203 can move the objective lens 102 in the plane perpendicular to the optical axis z over a distance of about d=1 mm (peek to peek). About 14 to 15 images of 70 μm×70 μm can thus be taken by laterally displacing the lens 102. The second pair of lenses 102, 102 is staggered with respect to the first pair 102, 102 by about 1 mm, the third pair 102, 102 by about 2 mm, etc., until the twelfth pair 102, 102.

By combining the lateral displacement of the objective lenses 102 (x-direction) with a displacement in the y-direction performed by a linear stepper motor (not shown in FIG. 2), the whole area of a batch of twelve samples (having a dimension of 2 cm×2 cm) can be imaged.

As an alternative to the embodiment of FIG. 2, it is also possible that only a single sample 101 is scanned (or less than twelve samples).

In order to further reduce a dead time, the twelve samples 211, 221, 231, . . . , 241 can be placed on a rotating stage 301, as shown in the apparatus 300 shown in FIG. 3. A rotation direction is indicated by a curved arrow 302.

Therefore, FIG. 3 shows an array microscope 300 using 24 actuators 203. It is possible to rotate the samples 101 and to keep the optical arrangement 100 fixed. Alternatively, it is possible to rotate the optical arrangements 100 and to keep the samples 101 fixed.

In the following, a method of using the microscope arrays 200, 300 for DNA cytometry will be explained. The following steps may be carries out.

1. Staining of the cells with Fuelgen staining.

2. Imaging the entire sample area 101 with the array of microscopes 200, 300 for M different focus heights (for instance M=7). The cell nuclei have to be in focus to be able to determine a correct IOD so that the sample 101 is imaged at several heights for each position.

3. Creating M images of the complete sample 101.

4. Detecting for each cell in a sample 101 the position of the nucleus and the height for which the nucleus is in focus.

5. Determining the transmission of the IOD for each nucleus.

6. Selecting the cells with the highest IOD in the sample for further processing by a pathologist.

In an alternative embodiment, the microscope functions with a different contrast mechanism (see FIG. 1). For example, placing a high-pass wavelength filter in the light path, the microscope can be easily adapted for a fluorescence contrast. Similarly, by placing a phase plate in the light path the microscope can be easily adapted for phase contrast. Images of the sample can be made with an absorption contrast method, with fluorescence contrast and/or with phase contrast in order to improve the accuracy of the image analysis processed that determines the IODs for the nuclei of the cells.

In the described embodiments, the imaging system is operated in a transmission mode. Alternatively, an imaging system according to an exemplary embodiment may be operated in a reflection mode or in a fluorescence mode (for instance using epi illumination).

It should be noted that the term “comprising” does not exclude other elements or features and the “a” or “an” does not exclude a plurality. Also elements described in association with different embodiments may be combined. It should also be noted that reference signs in the claims shall not be construed as limiting the scope of the claims.

1. A device (100) for imaging an object (101), wherein the device (100) comprises
an objective lens (102) adapted to manipulate a beam of electromagnetic radiation (103) after interaction with, particularly transmitted through, the object (101);
a collimator lens (104) adapted to manipulate the beam of electromagnetic radiation (103) transmitted through the objective lens (102);
an actuator (105) adapted for displacing the objective lens (102) in a direction essentially parallel and in at least one direction essentially perpendicular to a propagation direction of the beam of electromagnetic radiation (103) between the objective lens (102) and the collimator lens (104);
wherein the objective lens (102) and the collimator lens (104) are arranged so that the beam of electromagnetic radiation (103) between the objective lens (102) and the collimator lens (104) is essentially parallel.

2. The device (100) according to claim 1,
comprising a further objective lens (102), wherein the objective lens (102) and the further objective lens (102) are grouped to form a group of objective lenses (102).

3. The device (100) according to claim 1,
wherein the objective lens (102) and the collimator lens (104) are arranged so that sub-beams of the beam of electromagnetic radiation (103) originating from the same portion (106a, 106b) of the object (101) and being directed towards the same portion (107a, 107b) of a detector (108) are essentially parallel between the objective lens (102) and the collimator lens (104).

4. The device (100) according to claim 1,
comprising a phase plate (109) arranged, in a propagation direction of the beam of electromagnetic radiation (103), downstream of the objective lens (102).

5. The device (100) according to claim 1,
comprising a wavelength filter (109), particularly a high-pass wavelength filter, arranged, in a propagation direction of the beam of electromagnetic radiation (103), downstream of the objective lens (102).

6. (canceled)

7. An apparatus (200) for imaging an object (101), wherein the apparatus (200) comprises
an array formed by a plurality of devices (100) according to claim 1.

8. The apparatus (200) according to claim 7,
wherein the objective lenses (102) of the plurality of devices (100) are spatially staggered with respect to one another.

9. (canceled)

10. The apparatus (200) according to claim 2,
wherein the groups of objective lenses (102) of the devices (100) are spatially staggered with respect to one another along the direction essentially perpendicular to the propagation direction of the beam of electromagnetic radiation (103) along which direction the groups of objective lenses (102) of the devices (100) are displaceable by the actuators (105).

11. The apparatus (200) according to claim 7,
comprising a motion mechanism adapted for displacing the objective lenses (102) of the plurality of devices (100) relative to the object (101) in a direction essentially perpendicular to the direction essentially parallel and to the direction essentially perpendicular to the propagation direction of the beam of electromagnetic radiation (103).

12. (canceled)

13. (canceled)

14. The apparatus (200, 300) according to claim 11,
wherein the motion mechanism is adapted for displacing the objective lenses (102) of the plurality of devices (100) relative to the object (101) by at least one of the group consisting of a relative linear displacement and a relative rotation.

15. The apparatus (200) according to claim 1,
comprising an electromagnetic radiation source (110) adapted to generate the beam of electromagnetic radiation (103) to be directed to the object (101).

16. (canceled)

17. The apparatus (200) according to claim 15,
wherein the electromagnetic radiation source (110) is adapted to generate the beam of electromagnetic radiation (103) of at least one of the group consisting of optical light, infrared radiation, ultraviolet radiation, and X-rays.

18. The apparatus (200) according to claim 7,
comprising a detector unit (108) comprising an array of detector elements arranged to detect the beam of electromagnetic radiation (103) transmitted through the collimator lenses (104) of the plurality of devices (100).

19. The apparatus (200) according to claim 18,
wherein the detector unit (108) is adapted to detect the image of the object (101) and is adapted to detect an integrated optical density.

20. The apparatus (200) according to claim 7,
adapted to image the object (101) for a plurality of focal positions.

21. (canceled)

22. The apparatus (200) according to claim 7,
adapted as at least one of the group consisting of a microscope array, a cytometry device, a DNA cytometry device, a cancer detection device, a cancer screening device, a high throughput screening device, a malaria screening device, a cell imaging device, array imaging, and a multi-well plate scanner.

23. A method of imaging an object (101), wherein the method comprises
manipulating, by an objective lens (102), a beam of electromagnetic radiation (103) after interaction with, particularly after transmission through, the object (101);
manipulating, by a collimator lens (104), the beam of electromagnetic radiation (103) transmitted through the objective lens (102);
displacing the objective lens (102) in a direction essentially parallel and in a direction essentially perpendicular to a propagation direction of the beam of electromagnetic radiation (103) between the objective lens (102) and the collimator lens (104);
arranging the objective lens (102) and the collimator lens (104) so that the beam of electromagnetic radiation (103) between the objective lens (102) and the collimator lens (104) is essentially parallel.

24. The method of claim 23,
comprising imaging the object (101) for at least one application of the group consisting of microscopy, cytometry, DNA cytometry, cancer detection, cancer screening, high throughput screening, malaria screening, cell imaging, array imaging, and multi-well plate scanner DNA cytometry.

25. The method of claim 23, further comprising
adjusting a focus setting by displacing the objective lens (102) in the direction essentially parallel to the propagation direction of the beam of electromagnetic radiation (103) between the objective lens (102) and the collimator lens (104);
acquiring data related to an image of at least a portion of the object (101),
subsequently displacing the objective lens (102) in the direction essentially perpendicular to the propagation direction of the beam of electromagnetic radiation (103) between the objective lens (102) and the collimator lens (104),
acquiring data related to another image of at least another portion of the object (101),
processing the data related to the image of the portion of the object (101) and the data related to the other image of the other portion of the object (101) to form an overall image of the object (101).

26. The method of claim 25,
further comprising re-adjusting the focus setting before acquiring the data related to the other image of the other portion of the object (101).
